(19) United States
(12) Patent Application Publication
(10) Pub. No.: US 2005/0230697 A1
(43) Pub. Date: Oct. 20, 2005

(54) Hyperboloid-drum structures and method of fabrication of the same using ion beam etching

(75) Inventors: O'Dae Kwon, Kyungsangbuk-do (KR); Jun-Youn Kim, Kyungsangbuk-do (KR); Sung-Jae An, Kyungsangbuk-do (KR)

Correspondence Address: KENNEDY COVINGTON LOBDELL & HICKMAN, LLP, 214 N. TRYON STREET, HEARST TOWER, 47TH FLOOR, CHARLOTTE, NC, 28202, US

(73) Assignee: POSTECH Foundation, Kyungsangbuk-do (KR)

(21) Appl. No.: 11/078,227

(22) Filed: Mar. 11, 2005

(30) Foreign Application Priority Data
Apr. 20, 2004 (KR) 10-2004-0026981

(51) Int. Cl. H01L 29/22; H01L 33/00; H01L 31/0336

(52) U.S. Cl. 257/95; 257/623; 257/94; 257/103; 257/14

(57) ABSTRACT

The present invention relates to a method of mass fabricating a hyperboloid-drum element which is uniform in size and with the diameter of an active layer (active region or gain medium) ranging from tens of nm to less than a few μm, and to an element fabricated thereby. According to the present invention, the fabrication method of the hyperboloid-drum element comprises forming an epitaxial layer which includes an n-type semiconductor joined with a p-type semiconductor on a substrate and an active region near a border region and a boundary between the n-type semiconductor and the p-type semiconductor; and etching the epitaxial layer into a shape of the hyperboloid-drum having the minimum diameter at the active region by an ion-beam etching method. The hyperboloid-drum element fabricated in accordance with the present invention has advantages of uniformity in size and good reproducibility.

### FIELD OF THE PRESENT INVENTION

The present invention relates to a method of fabricating a structure with a size ranging from nanometers to micrometers, and in particular, to a mass fabrication method for a hyperboloid-drum element of uniform size with an active layer (region or gain medium) diameter ranging from tens of nm to less than a few μm and the element fabricated thereby.

### BACKGROUND OF THE INVENTION

Recently, examination of elements of nanoscale size has been regarded as an important topic in the scientific field due to their unusual electrical and optical characteristics. At present, worldwide studies on nanoscale phenomena have been extensively carried out and published, especially regarding the fabrication methods and characteristics of an electronic element or an optical device in nanometer scale consisting of the quantum dot.

For the case of a semiconductor laser in particular, the fabrication of a nano-laser using the quantum dot needs a reflecting mirror placed on top and bottom of the quantum dot made by a self-assembled growth (SAG) method in the active region of a conventional laser structure where resonation occurs. And the nano-laser has been made by electron beam lithography and etching having a high resolution among the conventional fabrication method for the semiconductor laser.

However, it is difficult to achieve ideal characteristics because of the difficulties in acquiring process reproducibility and uniformity in the size, the shape, and the position of the quantum dot during the self-assembled growth process. In particular, for the fabrication of a single photon source (SPS), though it is ideal to locate a single quantum dot in a microcavity, i.e., the active region of the element, there is no certain method to achieve the ideal condition in the mass scale. Furthermore, it is difficult to achieve the metallic deposition process on the cap for electrical pumping due to the small size of MESA ranging from tens of no to hundreds of nm formed by the self-assembled growth method.

### SUMMARY OF THE INVENTION

In accordance with the present invention a reproducible method is provided to mass produce a hyperboloid-drum structure using ion-beam etching.

Further in accordance with the present invention a hyperboloid-drum structure with an active region of adjustable size is provided to be used for producing an optical element and an electronic element in nanoscale.

In an exemplary embodiment of the present invention, a hyperboloid-drum element includes a p-type semiconductor and an n-type semiconductor joined at their boundary, and an active region which is formed near a border region including the boundary. In order to have a minimum diameter at the active region, the hyperboloid-drum element is in a shape such that the diameter decreases gradually from the outer end of the n-type semiconductor and the p-type semiconductor as it nears the border region.

An intrinsic semiconductor can be placed between the n-type semiconductor and the p-type semiconductor and joined with them. The active region in this case is formed near the border region which includes the intrinsic semiconductor and each of the boundaries of the intrinsic semiconductor between the n-type semiconductor and the p-type semiconductor.

The diameter of the active region is featured with the range of tens of nm to several μm. A base material can be selected from the group consisting of GaAs, GaN, ZnSe, SiC, and InP.

In another exemplary embodiment of the present invention, a hyperboloid-drum element comprises an active region having a quantum well structure; an n-type barrier layer and a p-type barrier layer formed on both surfaces of the active region, respectively; an n-type distributed Bragg reflector (DBR) placed outside of the n-type barrier layer; and a p-type distributed Bragg reflector (DBR) placed outside of the p-type barrier layer and in a shape such that a minimum diameter occurs at the active region and the diameter decreases gradually with distance from each of the distributed Bragg reflectors toward the active region so that the quantum dot is positioned at the active region.

The diameter of the active region is featured with the range of tens of nm to several μm, and GaAs is the base material of the active region.

Also, an n-type AlGaAs layer is provided as the n-type barrier layer, and a p-type AlGaAs layer is provided as the p-type barrier layer. The distributed Bragg reflector can be deposited with alternating layers of Al_{0.3}Ga_{0.7}As with a high refractive index, and Al_{0.9}Ga_{0.1}As with a low refractive index, and each of the layers is λ/4 in thickness.

In an exemplary embodiment of the present invention, a fabrication method of the hyperboloid-drum element comprises forming an epitaxial layer which is made by joining an n-type semiconductor and a p-type semiconductor on the substrate and includes an active region near a border region and a boundary between the n-type semiconductor and the p-type semiconductor; and etching the epitaxial layer into the shape of the hyperboloid-drum having the minimum diameter at the active region by the ion-beam etching method.

The substrate can be made of a base material selected from the group consisting of GaAs, GaN, ZnSe, SiC, and InP.

The etching the epitaxial layer includes manufacturing a photoresist mask using photolithography, and etching the epitaxial layer into a shape of the hyperboloid-drum through the manufactured mask. It is preferable in the etching process to have an acute angle between the incident ion beam and the normal direction of the substrate where the epitaxial layer is formed.

Corrosive gases such as BCl₃ and Cl₂ can be used in the etching process, and an inert gas ion beam is preferable as the ion beam.

After the ion-beam etching, wet etching can be carried out to prevent damage to the sample surface by the ion-beam etching process. To prevent natural oxides from forming on the surface, a surface treatment can be done by ammonium sulfide treatment. And in order to prevent natural oxides from forming on the surface after the ion-beam etching, a plasma treatment can be possible by using one or more gases selected from the group consisting of N₂, H₂, and NH₃.

In another exemplary embodiment of the present invention, a fabrication method of the hyperboloid-drum element comprises forming an epitaxial layer having the active region on a substrate, and etching the epitaxial layer into the shape of the hyperboloid-drum having the minimum diameter at the active region by the ion-beam etching method. The forming the epitaxial layer includes forming an n-type distributed Bragg reflector on an n⁺ doped substrate; forming an n-type barrier layer on top of the n-type distributed Bragg reflector; forming an active region with a quantum well on top of the n-type barrier layer; forming a p-type barrier layer on top of the active region; and forming a p-type distributed Bragg reflector on top of the p-type barrier layer.

The etching the epitaxial layer includes manufacturing a photoresist mask by using photolithography; and etching the epitaxial layer into the shape of the hyperboloid-drum through the manufactured mask. It is preferable in the etching process to have an acute angle between the incident ion beam and the normal direction of the substrate where the epitaxial layer is formed.

The fabrication method of the hyperboloid-drum element includes further coating the outer surface of the p-type distributed Bragg reflector with polyimide and to planarize it; and forming an electrode by etching the polyimide and depositing Cr/Au.

In the fabrication method of the hyperboloid-drum element of the present invention described above, it is possible to adjust the size easily and to acquire reproducibility for mass production due to etching the active region with the quantum well into the size of tens to hundreds of run without using the quantum dot in the SAG method. Furthermore, it is easy to deposit a metal electrode on the top surface of the hyperboloid-drum because the top surface can be made in microscale, though the active region of the hyperboloid-drum structure in this case is in nanoscale. Therefore, it is possible to do electric pumping as well as optical pumping.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a schematic diagram of a hyperboloid-drum element according to an exemplary embodiment of the present invention.

FIGS. 2A to 2E are process diagrams showing a sequence to fabricate a hyperboloid-drum element according to an exemplary embodiment of the present invention.

FIGS. 3A and 3B are schematic diagrams which define a forming angle of a hyperboloid depending on an angle between an incident ion beam and a substrate in a fabrication process according to an exemplary embodiment of the present invention.

FIG. 4 is a schematic diagram of the chemically assisted ion-beam etching system used in an experiment for the present invention.

FIG. 5 is a photograph showing the hyperboloid-drum device according to an exemplary embodiment of the present invention.

FIG. 6 is a graph which shows variation of sidewall angle (α) depending on the variation of angle (θ) between an incident ion beam and a substrate in a chemically assisted ion-beam etching process.

FIG. 7 is a graph showing that shapes of the waist (an active region) of a hyperboloid-drum element and a top surface region (where metal is to be deposited) vary with the variation in size of the CAIBE photoresist (PR) mask, depending on angle (θ) between an incident ion beam and a substrate.

FIG. 8 shows scanning electronic microscope images of a hyperboloid-drum fabricated according to an exemplary embodiment of the present invention. FIG. 8(b) is a magnified image of the active region shown in FIG. 8(a), and FIG. 8(d) is a magnified image of the active region shown in FIG. 8(c).

FIG. 9 is a graph which shows variation of an optical power versus bias current of a hyperboloid-drum element with an active region diameter of 600 nm fabricated according to an exemplary embodiment of the present invention.

### DETAILED DESCRIPTION OF PREFERRED EMBODIMENTS

Reference will now be made in detail to embodiments of the present invention, examples of which may be illustrated in the accompanying drawings.

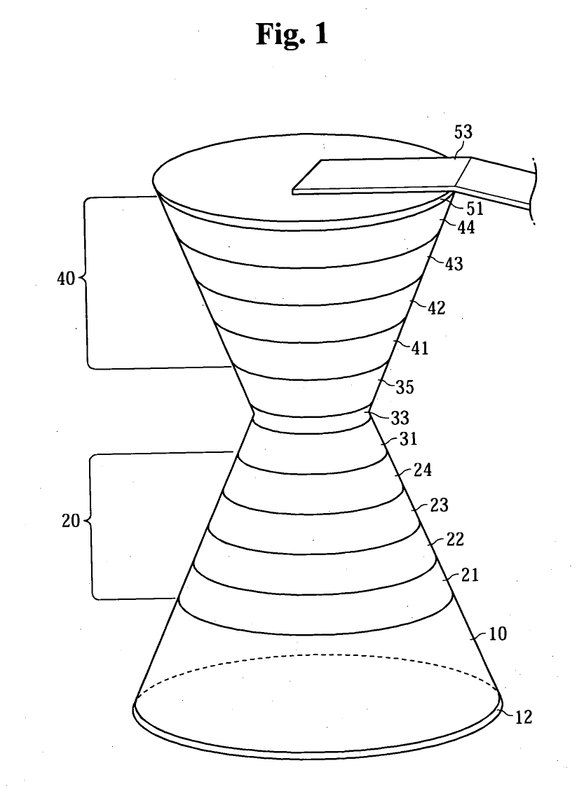

FIG. 1 is a schematic diagram of the hyperboloid-drum element according to an exemplary embodiment of the present invention.

Referring to FIG. 1, a hyperboloid-drum element has an active region 33 with a quantum well structure, and an n-type barrier layer 31 and a p-type barrier layer 35 are placed on both surfaces of the active region 33, respectively. And, ann-type distributed Bragg reflector (DBR) 20 is placed on the outside of the n-type barrier layer 31, and a p-type distributed Bragg reflector (DBR) 40 is placed on the outside of the p-type barrier layer 35.

The active region 33 has a quantum well structure such that both surfaces of a non-doped GaAs layer are surrounded with the barriers 31, 35 including the non-doped AlGaAs layer with a higher energy level and which restricts the holes and the electrons coming through the distributed Bragg reflectors 20 and 40 doped to be n-type and p-type, respectively.

The n-type distributed Bragg reflector 20 has a structure with alternating layers of the deposited Al_{0.3}Ga_{0.7}As layer 21 and 23 with a high refractive index, and the Al_{0.9}Ga_{0.1}As layer 22 and 24 with a low refractive index. Similarly, the p-type distributed Bragg reflector 40 has a structure with alternating layers of the deposited Al_{0.3}Ga_{0.7}As layer 41 and 43 with a high refractive index, and the Al_{0.9}Ga_{0.1}As layer 42 and 44 with a low refractive index. Each of these layers is λ/4 in thickness, and is preferably formed with a linearly varying aluminum mole fraction in order to reduce the series resistance between them.

On the other hand, the structure can be deposited by a metal organic chemical vapor deposition (MOCVD) method on the n+ doped GaAs substrate 10. And, the structure is in the shape of the hyperboloid-drum which has a minimum diameter at the active region and of which diameter decreases gradually away from the distributed Bragg reflectors 20 and 40 or the substrate 10 toward the active region 33 so that the quantum dot is positioned at the active region. Such a structure of the hyperboloid-drum can be fabricated by ion-beam etching.

The hyperboloid-drum made by the etching process reduces the active region 33, and can therefore lower the threshold current necessary to start the emission in the laser device with such a structure. In particular, when the active region 33 is fabricated as small as nanoscale to be a quantum dot, the quantum restriction effect occurs, and such a device can be used in the application for a single photon source and a single electron transistor.

An AuGe/Ni/Au layer deposited on the bottom surface of the n-type GaAs substrate 10 forms an n-type electrode 12, and the Cr/Au layer deposited on the top surface of the p-type distributed Bragg reflector 40 forms a p-type electrode 53. After the p-type distributed Bragg reflector 40 is coated with polyimide and planarized, the p-type electrode 53 is made by deposition of the Cr/Au layer on the etched top surface of the p-type distributed Bragg reflector 40.

In the element with the etched shape hyperboloid-drum, the size of the uppermost layer is microscale where the metal electrode is deposited for electrical pumping, while the active region 33 is in nanoscale. Therefore, it is possible to use a conventional photolithography process for patterning to deposit the metal electrode. In the case of a cylinder shape instead of the hyperboloid-drum shape, it is extremely difficult to use the patterning on the surface in nanoscale by the conventional photolithography process due to the same diameter of the uppermost layer with that of the active region 33 in nanoscale. Therefore, the etched shape of the hyperboloid-drum makes it possible to use optical pumping immediately after the etching process, and the electrical pumping after depositing the electrode by the post process.

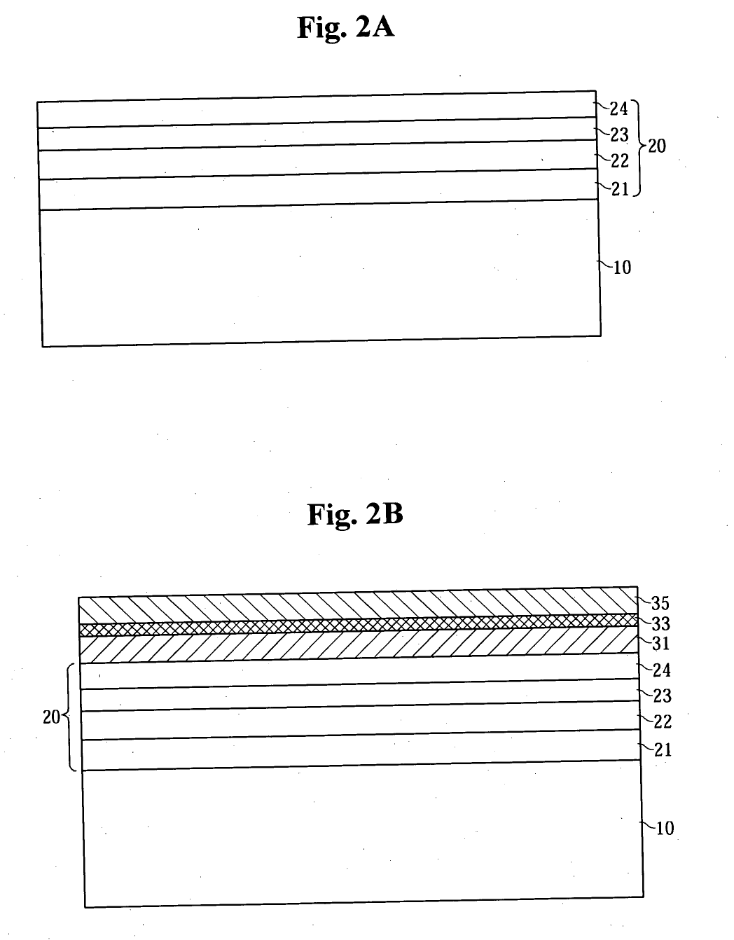

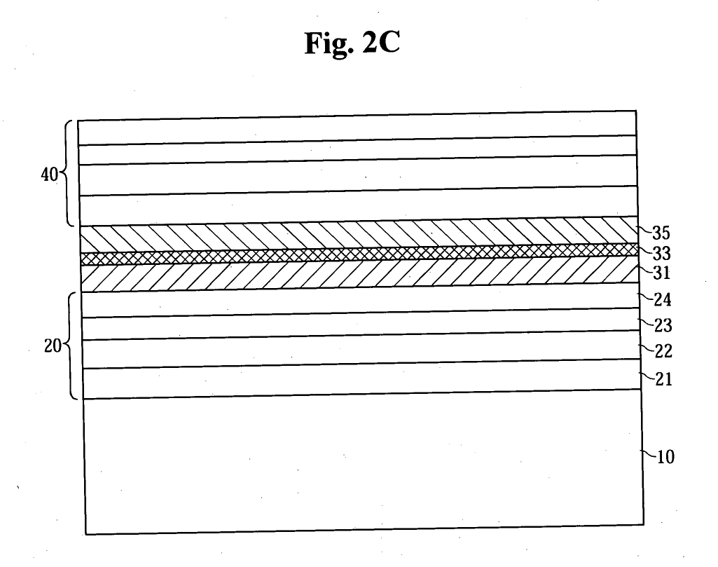

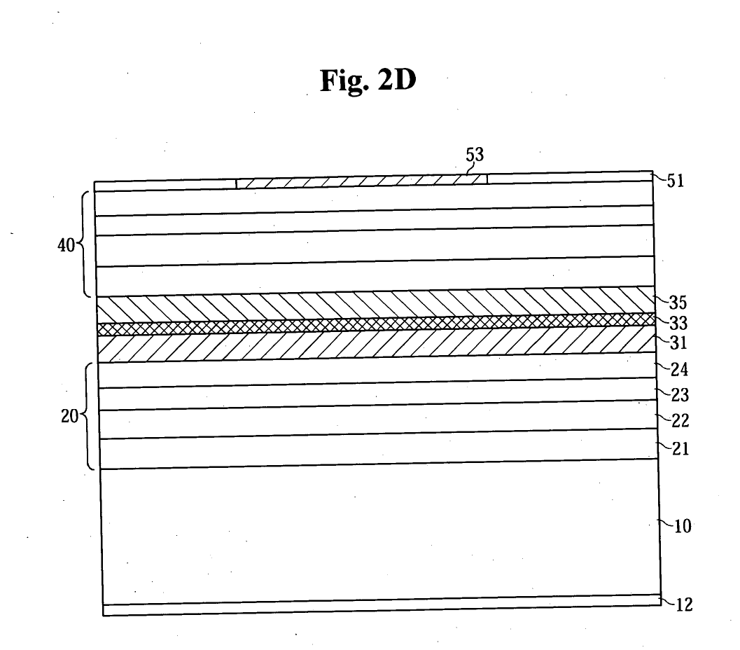

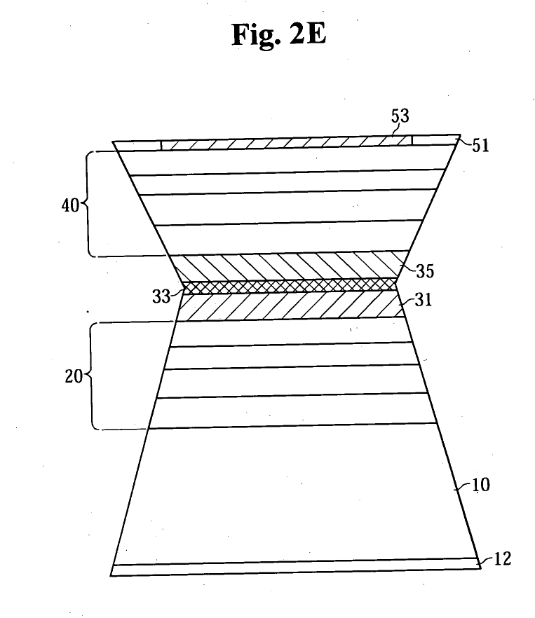

FIGS. 2A to 2E are process diagrams showing a sequence to fabricate the hyperboloid-drum element according to an examplary embodiment of the present invention.

In this embodiment, an epitaxial layer with the active region 33 is formed on the substrate. The hyperboloid-drum element is made by the ion-beam etching process to shape the epitaxial layer into the hyperboloid-drum of which minimum diameter is occurred at the active region 33. The epitaxial layer is deposited on the substrate by the metal organic chemical vapor deposition (MOCVD) method.

Referring to FIGS. 2A to 2E, the formation of the epitaxial layer undergoes the following steps.

First, the n-type distributed Bragg reflector 20 is formed on the n+ doped substrate 10. To form the n-type distributed Bragg Reflector 20, each λ/4 thick layer is deposited with alternating Al_{0.3}Ga_{0.7}As layers 21 and 23 with a high refractive index, and Al_{0.9}Ga_{0.1}As layers 22 and 24 with a low refractive index. Each layer can be formed with a linearly varying aluminum mole fraction in order to reduce the series resistance between them.

Then, the active region 33 is formed on the n-type distributed Bragg reflector 20. The active region 33 has the quantum well structure such that the AlGaAs layers as the barriers are placed on both sides of the non-doped GaAs layer.

Then, the p-type distributed Bragg reflector 40 is formed on the active region 33. To form the p-type distributed Bragg reflector 40, each λ/4 thick layer is deposited with the alternating Al_{0.3}Ga_{0.7}As layer 41 and 43 with a high refractive index and Al_{0.9}Ga_{0.1}As layer 42 and 44 with a low refractive index. Each layer can be formed with a linearly varying aluminum mole fraction in order to reduce the series resistance between them.

An n-type electrode 12 is deposited on the outer surface of the substrate with the epitaxial layer made by the process. To form the n-type electrode 12, an AuGe/Ni/Au layer is deposited on the outer surface of the substrate 10. Heat treatment is carried out to form the Ohmic contact in the temperature range of 400° C. to 500° C., for example at 425° C. where the AuGe, Ni, and Au are alloyed.

Then, in order to etch the layered structure into the shape of the hyperboloid-drum, a photoresist mask is made by first using photolithography, and then the epitaxial layer is etched as illustrated in FIG. 2E with the photoresist mask by the ion-beam etching process.

Ion beam etching systems such as RIE (reactive ion etching), CAIBE (chemically assisted ion beam etching), and ICP (inductive coupled plasma) are used. The basic components of the system are a vacuum chamber and an ion generator by an imposed DC or RF bias. The essence of these etching processes is the dry etching process that etches a sample by using the kinetic energy of the ion decomposed from the gas through the ion generator. Due to the linear motion of the ions in general, the etched shape can be changed by the change of the angle between the ion beam and the sample.

In order to etch the layered structure into the shape of the hyperboloid-drum in this embodiment, the target object to be etched is tilted with a given angle (θ) from the incident direction of the ion beam. The tilt angle θ is defined as the angle between the incident direction of the ion beam and the normal direction of the substrate, and can be properly selected in the range 0° to 90° to etch the layered structure into the shape of the hyperboloid-drum.

Also, the photoresist mask is patterned circularly by using the photoresist in this embodiment, and it plays a role of an etching mask, i.e., the etching is carried out on the region not covered with the mask and the region covered with the mask is not etched.

In the etching process, corrosive gases such as BCl₃ and Cl₂ are chemically used for the etching by an argon ion (Ar⁺) beam. The corrosive gases play a role of helping the ion etching by reacting chemically with the surface of the sample such as GaAs or AlGaAs to form a chemical compound which is easily broken and separated by the ion beam. The role of these corrosive gases can have an influence on the etching rate and the roughness of the etched surface.

The shape of the hyperboloid-drum can be etched by adjusting the angle between the ion beam and the substrate, the temperature of the sample, the distance between the ion source and the sample, and the flow rate of the corrosive gas.

After the chemically assisted ion-beam etching process, wet etching is carried out slightly to compensate for the damage to the sample surface resulting from the chemically assisted ion-beam etching process. To prevent natural oxides from forming on the surface, a surface treatment can be done by plasma treatment using gases such as N₂, H₂, or NH₃, or by an ammonium sulfide treatment using various solutions. Combination of the plasma treatment and the ammonium sulfide treatment can also be possible.

After this process, the polyimide 51 is coated on the whole sample, and planarized to deposit the metal electrode on the hyperboloid-drum element. Then, the p-type electrode 53 is made by the deposition of the Cr/Au layer on the etched top surface after etching the polyimide 51 to expose the top surface of the element.

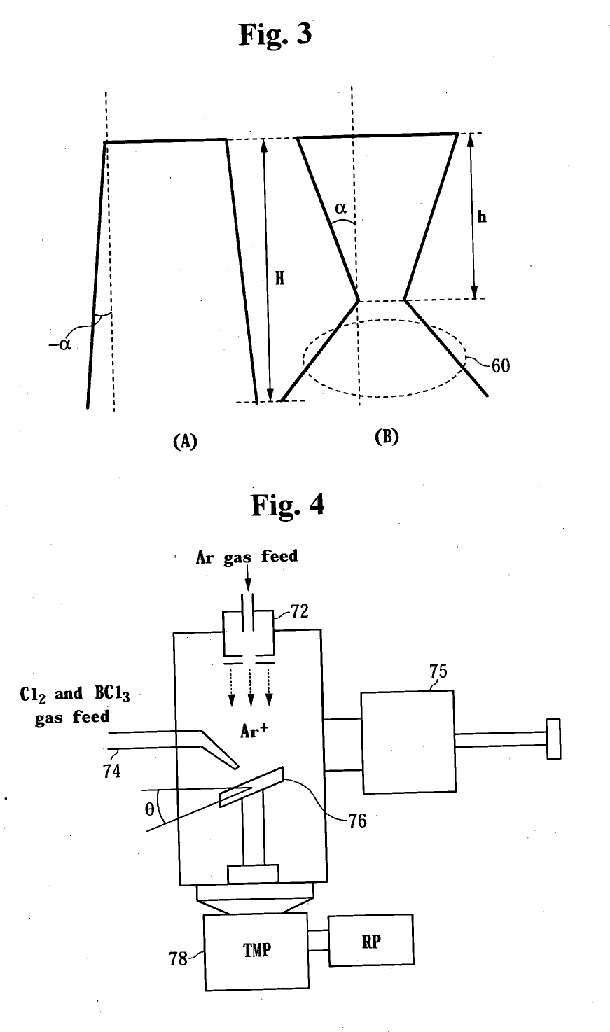

FIGS. 3A and 3B are schematic diagrams defining the forming angle of the hyperboloid that depends on the angle between the incident ion beam and the substrate.

In FIG. 3, α is the angle of the sidewall inclination of the element measured from the substrate normal. The etched sidewall has an outward-tapered (α<0°) shape when the tilt angle θ is small, as shown in FIG. 3A. Increase in the angle θ reduces the magnitude of the sidewall angle α and it is possible to have a vertical sidewall (α=0°) at a certain tilt angle θc. The inward-tapered sidewall profile (α>0°) shown in FIG. 3B is obtained when the tilt angle θ is bigger than θc.

The bottom part in FIG. 3B is the shadow region 60, which is an etched surface under the shadow of the mask for the ion beam. This shadow effect is used to obtain a nano-structure of the hyperboloid-drum in accordance with the present embodiment: a combination of the normally etched inward-tapered region and the outward-tapered shadow region results in the nano-structure of the hyperboloid-drum. H is the total height of the etched MESA, i.e., the height of the hyperboloid-drum, while h is the height from the active region to the top surface excluding the shadow region.

Although the embodiment describes the fabrication of a hyperboloid-drum structure by etching GaAs as a base material, the present invention is not limited to the base material and includes every structure that can be made to the hyperboloid-drum shape by chemically assisted ion-beam etching. Therefore, it is possible to fabricate the hyperboloid-drum structure from the base material such as GaN, ZnSe, SiC, and InP, which falls within the spirit and scope of the present invention.

### EXPERIMENTAL EXAMPLE

The CAIBE (Chemically assisted ion-beam etching) system for the experiment to make the element of the hyperboloid-drum is schematically shown in FIG. 4 and will be described in detail hereinafter. The system has a dual-grid Kaufman-type ion source 72 with a diameter of 3 cm.

For this experiment, the substrate fixed to the substrate holder 76 is rotated at 25 rpm, and its temperature is kept constant to assure etch uniformity and reproducibility. The tilt angle θ, which is the angle between the incident ion beam and the normal direction of the substrate, is adjusted to achieve the desired etched sidewall profile.

Also, the system has four nozzles 74 for gas injection, which are located near the substrate. The tips of the nozzles 74 are tilted with the substrate, so that the geometry of gas feeding does not change with the tilt angle. The gas flow rates for Ar, Cl₂, and BCl₃ are 5, 2, and 3 sccm, respectively.

While changing the tilt angle θ for a given beam energy and current, the distance between the substrate and ion source is kept constant at 13 cm to maintain the same beam profile.

The system has a load-lock chamber 75 and a turbomolecular pump CTMP) 78, which is rotated at 26,700 rpm. The background pressure is ˜1×10⁻⁶ Torr, and the pressure for CAIBE is ˜5.2×10⁻⁴ Torr.

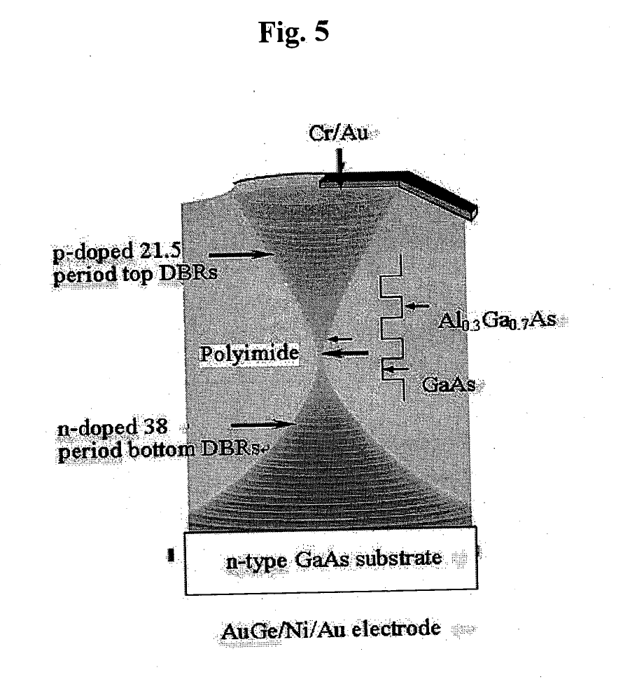

The hyperboloid-drum element is fabricated by the CAIBE method using the experiment system and is shown in FIG. 5.

The structure of the hyperboloid-drum device was fabricated on an n-type GaAs substrate grown by the metal organic vapor-phase epitaxy method. The structure consists of two distributed Bragg reflector (DBR) mirrors surrounding a one-λ cavity, which has three 80 Å GaAs quantum wells, Al_{0.3}Ga_{0.7}As barriers, and spacers. The thickness of one-λ cavity is 269.4 nm. There are 38 periods in the n-type bottom mirror and 21.5 periods in the p-type top mirror. The mirrors consist of alternating 419.8 Å Al_{0.15}Ga_{0.85}As layers and 488.2 Å Al_{0.95}Ga_{0.05}As layers. Between the layers, a 200 Å-thick, linearly graded AlGaAs layer was grown. The p-type and n-type distributed Bragg reflector mirrors were doped to a dose bigger than 10¹⁸ cm⁻³ with C and Si, respectively. The height of the nano-structure of the Hyperboloid-drum is 8 μm.

A masking layer ˜1.7 μ/m thick for CAIBE was fabricated with AZ5214 PR using a Karl Suss MJB3 contact aligner and a contact mask. The damage induced by the CAIBE process were removed by a H₂SO₄ polishing process, in which the samples were dipped into a H₂SO₄:H₂O₂:H₂O=1:8:1000 solution for 5 seconds. Subsequently, sulfur passivation followed to improve the intensity and lifetime of the laser. For the sulfur treatment, a 6% excess sulfur-containing (NH₄)₂Sₓ solution was used at 60° C., and the samples were dipped into the solution for 8 minutes. These sulfur-treated samples were loaded immediately into the plasma-enhanced chemical vapor deposition chamber of a downstream type, and they were prebaked first at 300° C. for 30 minutes in an NH₃ environment before deposition of a Si₃N₄ layer. This temperature treatment helps the excess sulfur not bonded to the GaAs surface to sublimate. After the sulfur passivation, a polyimide coating, etching for planarization, and evaporation of Cr/Au and AuGe/Ni/Au for p and n contacts followed. The polyimide layer reinforces the fragile nano-structure of the hyperboloid-drum.

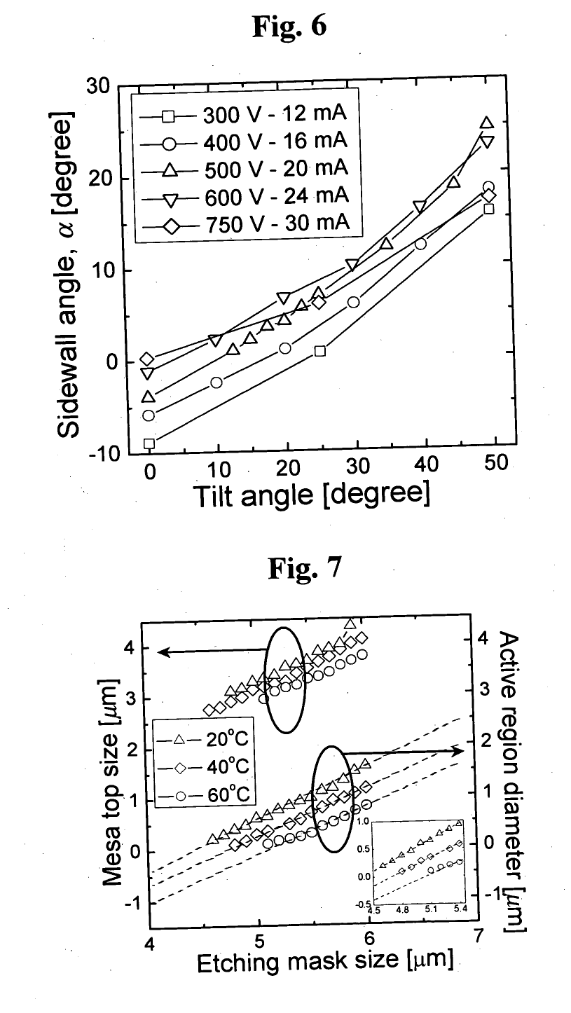

FIG. 6 shows the variation of the sidewall angle α with varying the tilt angle θ between the incident ion beam and the substrate.

The abscissa and the ordinate in FIG. 6 represent the tilt angle θ between the ion beam and the sample and the sidewall angle α, respectively. The direction of the ion beam is set to be vertical from top to bottom so that the sample is only tilted to adjust the angle between the ion beam and the sample. Also, the voltage and the current in the index box of FIG. 6 indicate the intensity of the ion beam, which can be represented by the product of the voltage and the current.

A negative α indicates an outward-tapered sidewall, and a positive α indicates an inward-tapered sidewall. All sidewalls are outward-tapered at θ=0°, except that fabricated with the 750 eV, 30 mA beam. For a given beam, the sidewall angle α increases when the tilt angle θ increases, and it is in the range of 15 to ˜25° at θ=50°. For a fixed θ, the sidewall angle α increases with increasing the beam energy and current.

According to this condition, it is ascertained that the transition in the shape from the trapezoid (at negative α) to the hyperboloid-drum (at positive α) occurs with the variation of the angle between the ion beam and the substrate.

FIG. 7 displays that the shape of the waist (the active region) of the hyperboloid-drum element and the top surface region (where metal is to be deposited) varies with the variation in the size of the CAIBE photoresist (PR) mask.

The process gas mixture for this experiment was Ar:Cl₂:BCl₃=5:2:3 with a total flow rate of 10 sccm. The beam energy, beam current, tilt angle θ, and etch time for CAIBE were 500 eV, 20 mA, 50°, and 27.5 min, respectively. The substrate temperature was kept constant during the CAIBE process at 20° C. (triangle), 40° C. (lozenge), and 60° C. (circle). At these temperatures, the effect of the substrate temperature on the erosion rate of mask is negligible, and the fabricated nano-structure of the hyperboloid-drum have top surfaces of nearly the same size, as shown in FIG. 7.

The observed loss on the mask diameter after CAIBE is approximately 1.6 μm. The diameter of the active region for a given substrate temperature increases in proportion to the mask size. When the substrate temperature is 20° C., the diameter of the active region for a mask size of 5.4 μm is ˜900 nm. The diameter of the active region decreases with increasing the substrate temperature because the desorption rates of reaction by-products increase with temperature. The diameter of the active region is reduced to ˜200 mm when the substrate temperature is 60° C.

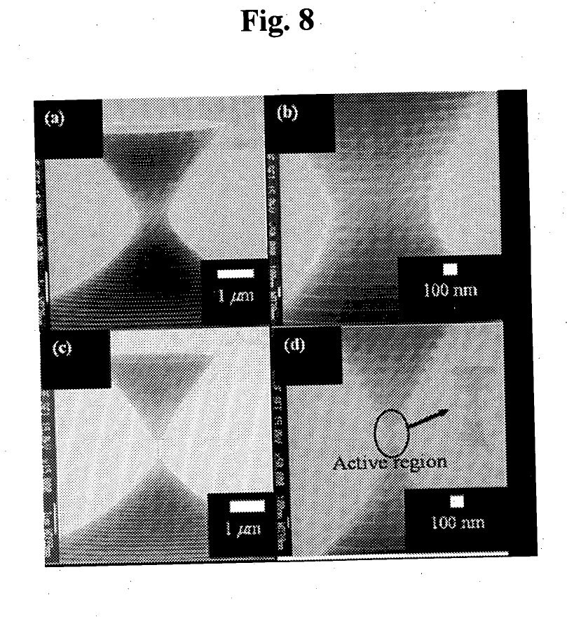

The SEM images of the fabricated hyperboloid-drum element are shown in FIG. 8. The structures shown in FIGS. 8(a) and 8(c) are fabricated at a substrate temperature 60° C. with mask sizes of 5.7 μm and 5.2 μm, respectively. Magnified images thereof are shown in FIGS. 8(b) and 8(d), respectively. Both structures have the same etched height of ˜8 μm. The active region diameters are 600 nm and 95 nm in FIGS. 8(b) and 8(d), respectively, demonstrating that a fabrication of the hyperboloid-drum element with a nanoscale active region is possible by adjusting the mask size.

Referring to FIG. 8, it is possible to accurately control the size of the mesa top by the size of the photoresist mask where the metal electrode is deposited depending on the etching condition and the size of the active region where the optical emission occurs. The size of the active region can be easily controlled by adjusting the size of the etching mask because the top region of the element is roughly linearly proportional to the size of its active region, depending on the size of the etching mask. Not only can this hyperboloid-drum element control the size of the active region in nanoscale where the emission occurs, but it also has an advantage for the electrical laser emission due to the large top area of the mesa where the electrode is deposited. The temperature in the index box indicates the temperature of the sample. The temperature of the sample can be controlled by heating/cooling the holder where the sample is put.

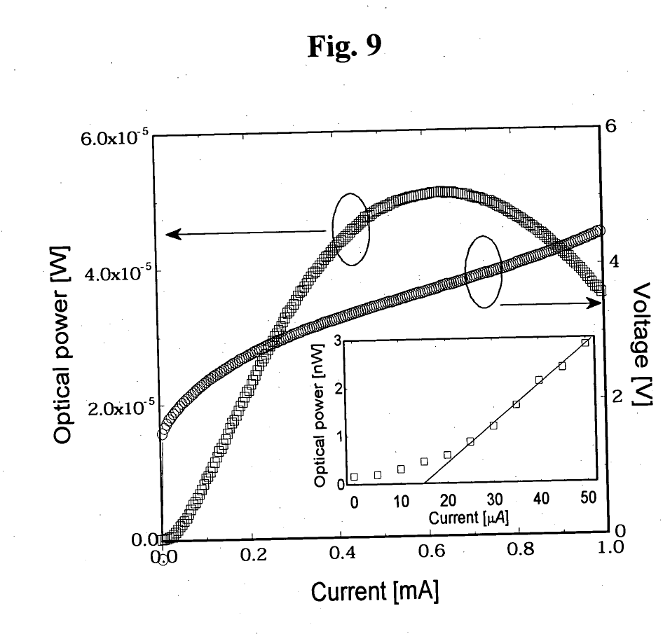

For the hyperboloid-drum element fabricated by an exemplary embodiment of the present invention, the light-current-voltage curves for the element with the active region diameter of 600 nm are shown in FIG. 9.

The emission of the optical element can be confirmed though the early characteristics of the light power vs. current of the test element are not significant.

Although preferred embodiments of the present invention have been described in detail hereinabove, it should be clearly understood that many variations and/or modifications of the basic inventive concept herein taught which may appear to those skilled in the art will still fall within the spirit and scope of the present invention, as defined in the appended claims.

1. A hyperboloid-drum element comprising:
a p-type semiconductor and an n-type semiconductor joined at a boundary; and
an active region that is formed near a border region including the boundary, which is of minimum diameter, and the diameter of the hyperboloid-drum element decreases gradually from the outer end of the n-type semiconductor and the p-type semiconductor toward the border region.

2. The hyperboloid-drum element of claim 1, wherein an intrinsic semiconductor is placed between the n-type semiconductor and the p-type semiconductor and is joined with the n-type semiconductor and the p-type semiconductor, and the active region is formed near the border region which includes the intrinsic semiconductor and each of boundaries of the intrinsic semiconductor between then-type semiconductor and the p-type semiconductor.

3. The hyperboloid-drum element of claim 1, wherein the diameter of the active region is in the range of tens of nm to several μm.

4. The hyperboloid-drum element of claim 1, wherein the base material of the active region is selected from the group consisting of GaAs, GaN, ZnSe, SiC, and InP.

5. A hyperboloid-drum element comprising
an active region having a quantum well structure;
an n-type barrier layer and a p-type barrier layer respectively formed on both surfaces of the active region;
an n-type distributed Bragg reflector (DBR) placed outside of the n-type barrier layer; and
a p-type distributed Bragg reflector (DBR) placed outside of the p-type barrier layer;
wherein the diameter of the hyperboloid-drum element decreases gradually away from each of the distributed Bragg reflectors and toward the active region such that a minimum diameter occurs at the active region where a quantum dot is positioned.

6. The hyperboloid-drum element of claim 5, wherein the diameter of the active region is in the range of tens of nm to several μm.

7. The hyperboloid-drum element of claim 5, wherein the base material of the active region is GaAs.

8. The hyperboloid-drum element of claim 7, wherein an n-type AlGaAs layer is provided as the n-type barrier layer, and a p-type AlGaAs layer is provided as the p-type barrier layer.

9. The hyperboloid-drum element of claim 7, wherein the distributed Bragg reflector is deposited with alternating layers of Al_{0.3}Ga_{0.7}As with a high refractive index, and Al_{0.9}Ga_{0.1}As with a low refractive index, each layer being λ/4 in thickness.

10. A fabrication method of a hyperboloid-drum element, comprising:
forming an epitaxial layer which comprises an n-type semiconductor joined with a p-type semiconductor on a substrate and including an active region near a border region and a boundary between the n-type semiconductor and the p-type semiconductor; and
etching the epitaxial layer into a shape of the hyperboloid-drum having a minimum diameter at the active region by an ion-beam etching method.

11. The fabrication method of the hyperboloid-drum element of claim 10, wherein the substrate is made of a base material selected from the group consisting of GaAs, GaN, ZnSe, SiC, and InP.

12. The fabrication method of the hyperboloid-drum element of claim 10, wherein the etching the epitaxial layer comprises manufacturing a photoresist mask using photolithography, and etching the epitaxial layer into a shape of the hyperboloid-drum through the manufactured mask.

13. The fabrication method of the hyperboloid-drum element of claim 12, wherein the etching is carried out with an acute angle between an incident ion beam and the normal direction of the substrate where the epitaxial layer is formed.

14. The fabrication method of the hyperboloid-drum element of claim 10, wherein a corrosive gas such as BCl₃ or Cl₂ is used in the etching step.

15. The fabrication method of the hyperboloid-drum element of claim 10, wherein an inert gas ion beam is used in the etching step.

16. The fabrication method of the hyperboloid-drum element of claim 10, wherein, after the ion-beam etching, wet etching is additionally carried out to prevent damage to the sample surface by the etching process.

17. The fabrication method of the hyperboloid-drum element of claim 10, wherein, after the ion-beam etching, a surface treatment is carried out by ammonium sulfide treatment to prevent natural oxides from forming on the surface.

18. The fabrication method of the hyperboloid-drum element of claim 10, wherein, after the ion-beam etching, plasma treatment is carried out by one or more gases selected from the group consisting of N₂, H₂, or NH₃ to prevent natural oxides from forming on the surface.

19. A fabrication method of a hyperboloid-drum element, comprising:
forming an epitaxial layer having an active region on a substrate, and
etching the epitaxial layer into a shape of the hyperboloid-drum having a minimum diameter at the active region by an ion-beam etching method,
wherein forming the epitaxial layer comprises:
forming an n-type distributed Bragg reflector on an n+ doped substrate;
forming an n-type barrier layer on top of the n-type distributed Bragg reflector;
forming an active region with a quantum well on top of the n-type barrier layer;
forming a p-type barrier layer on top of the active region; and
forming a p-type distributed Bragg reflector on top of the p-type barrier layer.

20. The fabrication method of the hyperboloid-drum element of claim 19, wherein the etching the epitaxial layer comprises manufacturing a photoresist mask by using photolithography; and etching the epitaxial layer into the shape of the hyperboloid-drum through the manufactured mask.

21. The fabrication method of the hyperboloid-drum element of claim 20, wherein the etching is carried out with an acute angle between an incident ion beam and the normal direction of the substrate where the epitaxial layer is formed.

22. The fabrication method of the hyperboloid-drum element of claim 19, further comprising:
coating the outer surface of the p-type distributed Bragg reflector with polyimide to flatten the outer surface of the p-type distributed Bragg reflector; and
forming an electrode by etching the polyimide and depositing Cr/Au.
